(19) United States
(12) Patent Application Publication
(10) Pub. No.: US 2014/0060619 A1
(43) Pub. Date: Mar. 6, 2014

(54) OPTICAL PROBE, APPARATUS AND SYSTEM

(71) Applicants: Joerg Peter Feist, London (GB); Sijiong Zhang, Nanjing (CN)

(72) Inventors: Joerg Peter Feist, London (GB); Sijiong Zhang, Nanjing (CN)

(21) Appl. No.: 13/878,882

(22) PCT Filed: Oct. 11, 2011
(86) PCT No.: PCT/GB11/01469

§ 371 Date: Nov. 19, 2013

(30) Foreign Application Priority Data
Oct. 11, 2010 (GB) 1017141.1

(51) Int. Cl. G02B 27/10; H01L 31/052; G01S 3/786

(52) U.S. Cl. CPC G02B 27/10; G01S 3/7861; H01L 31/0524
USPC 136/246; 250/203.1; 359/618; 348/135

(57) ABSTRACT

An optical system (3) for transferring light energy from a light source (1), in particular a moving light source, to a common aperture independent of the location of the light source within a field of view, wherein the light energy distribution is preferably substantially uniform over the area of the common aperture. A detection system comprises a light source 1 for irradiating a spot on a moving object 0, an optical probe assembly 3 for collecting light energy from the irradiated spot on the subject 0 when within a field of view of the probe assembly 3, and a photodetector 4.

The present invention relates to an optical probe and apparatus for transferring light energy from a light source, in particular a moving light source, to a common aperture independent of the location of the light source within a field of view, such as to be collected at the common aperture by, for example, sensors or photo-voltaic cells, and a detection system incorporating the same.

There are very many optical systems available which allow for the collection of light energy, in particular the detection of luminescence, such as phosphorescence and fluorescence.

Such systems are designed for use with static light sources, and do not conveniently allow for the detection of light energy from moving light sources, such as in the detection of the lifetime decay of an excitation spot on a turbine blade, or for the detection of light energy from a light source which is imprecisely aligned to the optical probe. In such systems, moving light sources present the particular difficulty that the detected intensity at any instant will be a function of the position in the field of view, requiring the instrumental function across the field of view to be accurately measured and also requiring the use of a de-convolution algorithm to extract the real signal.

It is an aim of the present invention to provide an optical probe and apparatus for transferring light energy from a light source, in particular a moving light source, to a common aperture independent of the location of the light source within a field of view, and a detection system incorporating the same.

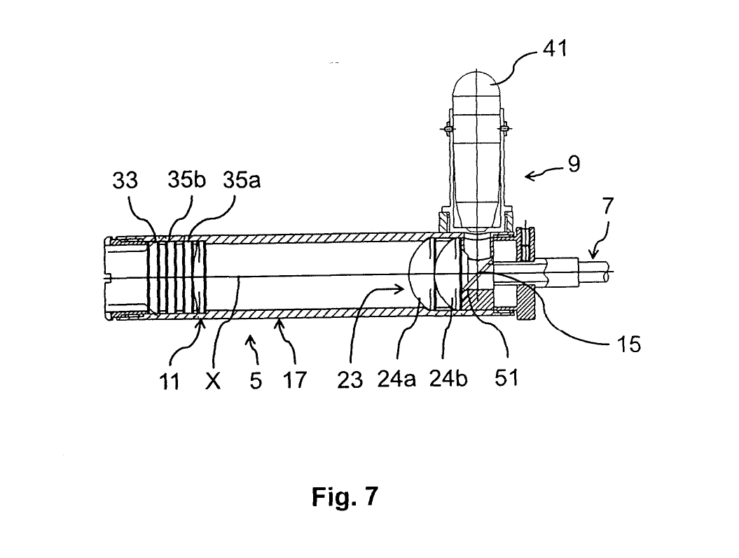

In addition to applications of the kind as mentioned above, that is, the detection of the lifetime decay of a fast-moving phosphor spot, the present inventors have recognized the application of the present invention to concentrated photo-voltaic (CPV) applications, which currently require a very precise alignment of the solar cells to the incident solar radiation. As illustrated in FIG. 7, deviation of only one degree to the angle of incidence gives rise to a reduction of nearly 50% in performance.

In existing systems, trackers are used to track the path of the sun and attempt to maintain a zero deviation in the angle of incidence. Whilst the path of the sun can be tracked quite accurately, the trackers are elaborate and expensive units, typically comprising about 20% of the total system cost, and, moreover, the trackers tend not to be durable, in being operated in hostile environments, and thereby requiring frequent maintenance.

The present invention, in providing a large acceptance angle allows operation with a simple tracker system, or indeed no tracker system at all.

Furthermore, the present inventors have recognized that the present invention would allow for the mounting of fixed solar panels in non-optimal directions by the use of asymmetric optics, where the first optical element is configured to have an angle of acceptance which is inclined at or near the optimal direction for a fixed solar panel at the given location.

In one aspect the present invention provides an optical system for transferring light energy from a light source, in particular a moving light source, to a common aperture independent of the location of the light source within a field of view, wherein the light energy distribution is preferably substantially uniform over the area of the common aperture.

In another aspect the present invention provides a probe assembly, comprising: a probe comprising the above-described optical system; and a light collector for collecting light energy transferred by the probe.

In a further aspect the present invention provides a detection system, comprising: a light source for irradiating a spot on a moving object; the above-described probe assembly for collecting light energy from the irradiated spot on the object when within a field of view of the probe; and a photodetector for measuring the intensity of the light energy collected by the probe.

In a yet further aspect the present invention provides a photovoltaic module comprising the above-described optical system, and a photovoltaic cell located at the common aperture of the optical system.

In a still further aspect the present invention provides a photovoltaic array comprising a plurality of the above-described photovoltaic modules.

In yet another aspect the present invention provides a photovoltaic array, comprising: a plurality of optical systems for transferring light energy from a light source, in particular a moving light source, to common apertures independent of the location of the light source within a field of view, wherein each optical system comprises a first optical element for focussing incident radiation from the light source to a focal point, and a second optical element for relaying the image of the first optical element to the common aperture independent of the location of the light source when within the field of view; and a plurality of photovoltaic cells located respectively at the common apertures of the optical systems.

In yet another aspect the present invention provides a photovoltaic system comprising: the above-described photovoltaic module or array; and a tracking mechanism for moving the photovoltaic module or array to follow the path of the sun.

Preferred embodiments of the present invention will now be described hereinbelow by way of example only with reference to the accompanying drawings, in which:

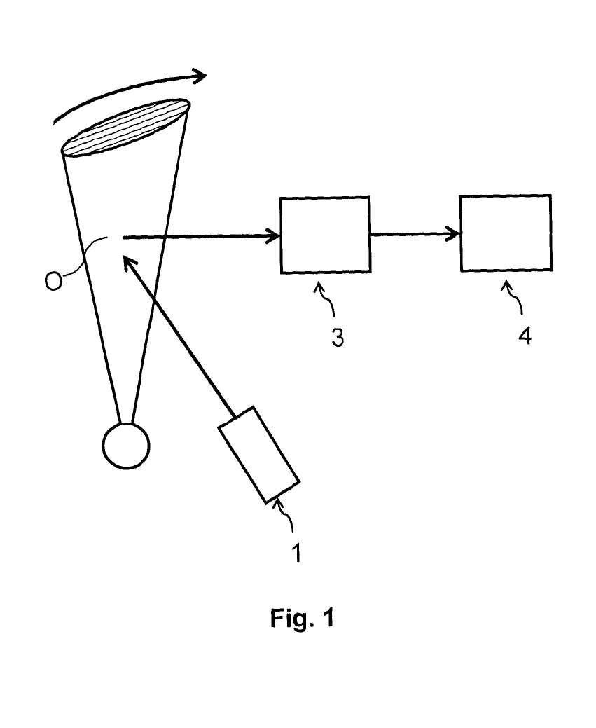

FIG. 1 illustrates a detection system in accordance with a preferred embodiment of the present invention;

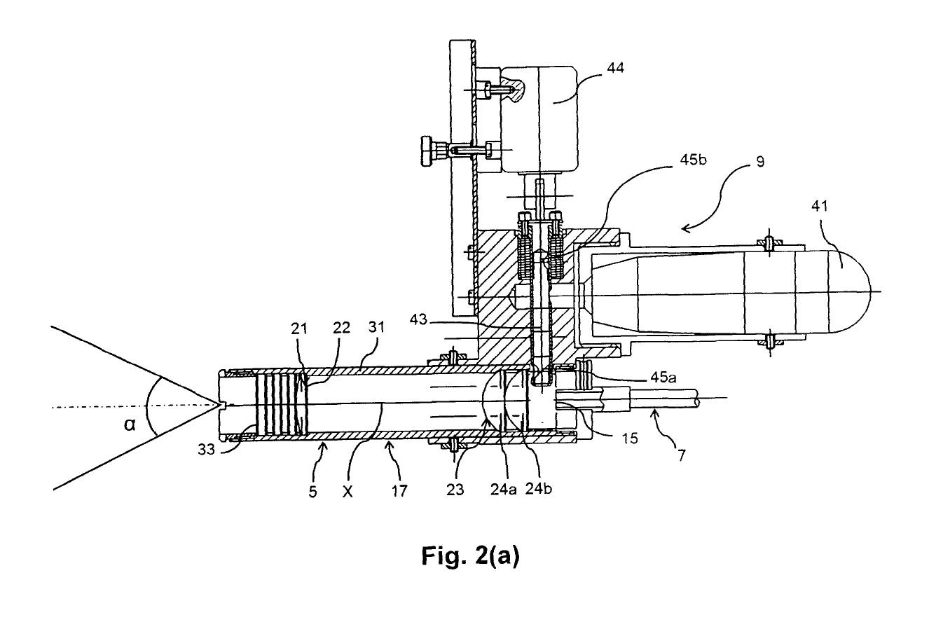

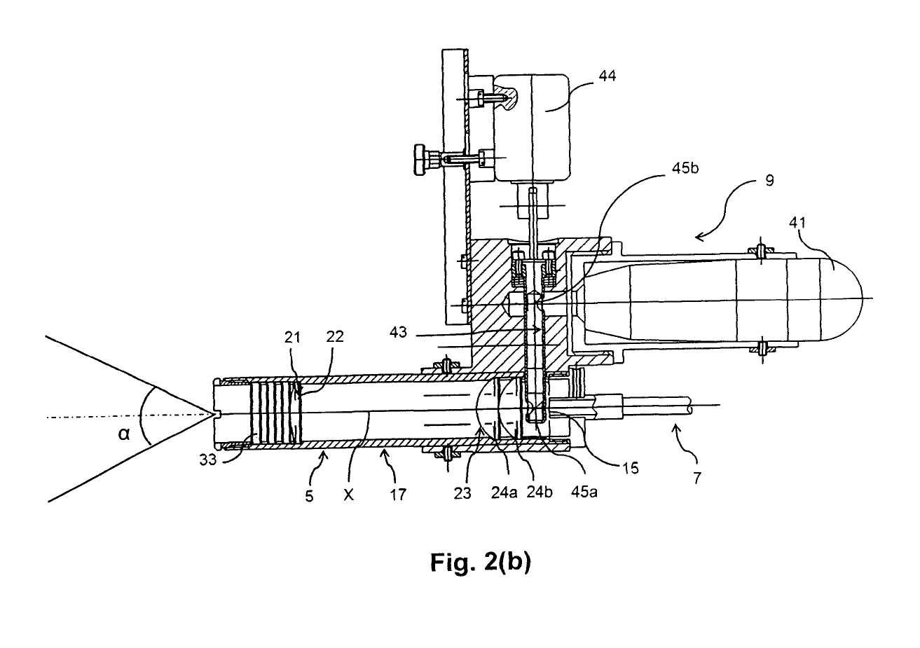

FIGS. 2(a) and (b) illustrate an optical probe assembly in accordance with a preferred embodiment of the present invention;

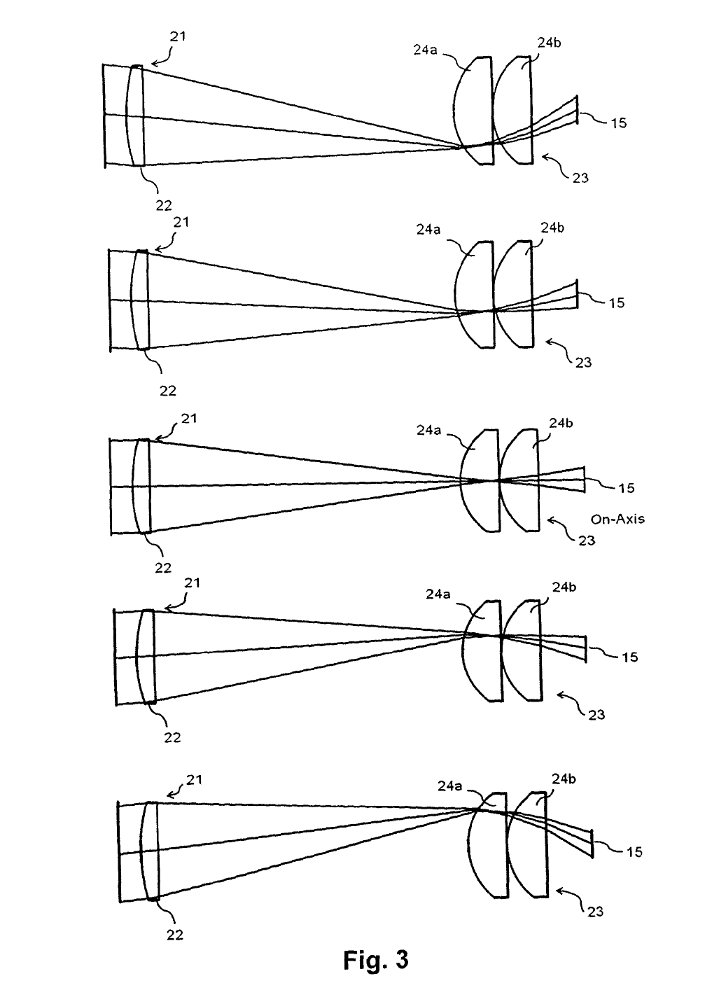

FIG. 3 illustrates ray diagrams for the optical probe assembly of FIGS. 2(a) and (b), which illustrate the focussing and relaying of light energy;

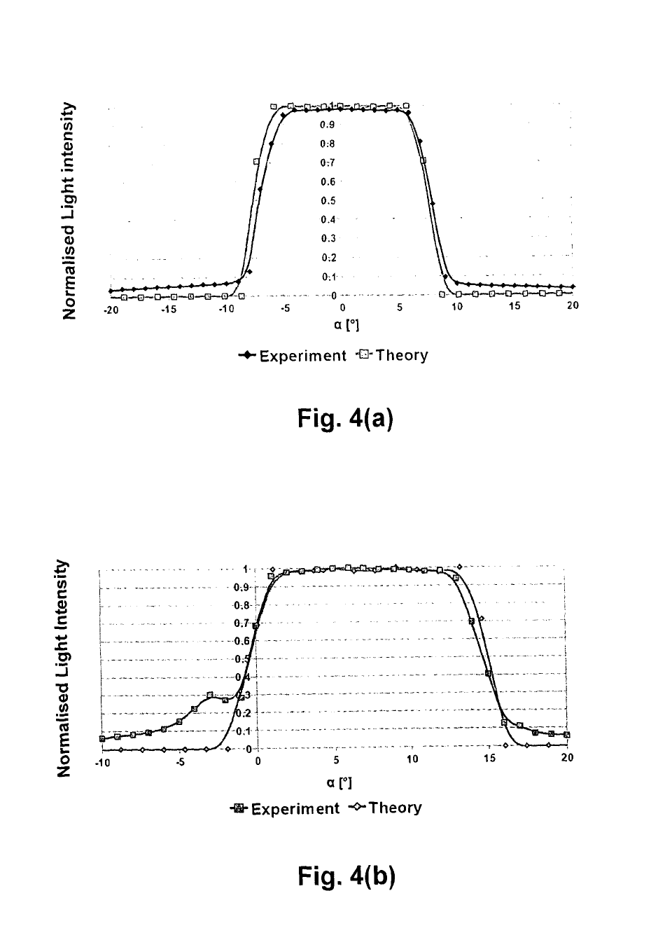

FIGS. 4(a) and (b) illustrate the measured and theoretical light intensities as a function of the angle of incidence (α) along two orthogonal (X, Y) axes for the probe of the probe assembly of the detection system of FIG. 1 in Example #1;

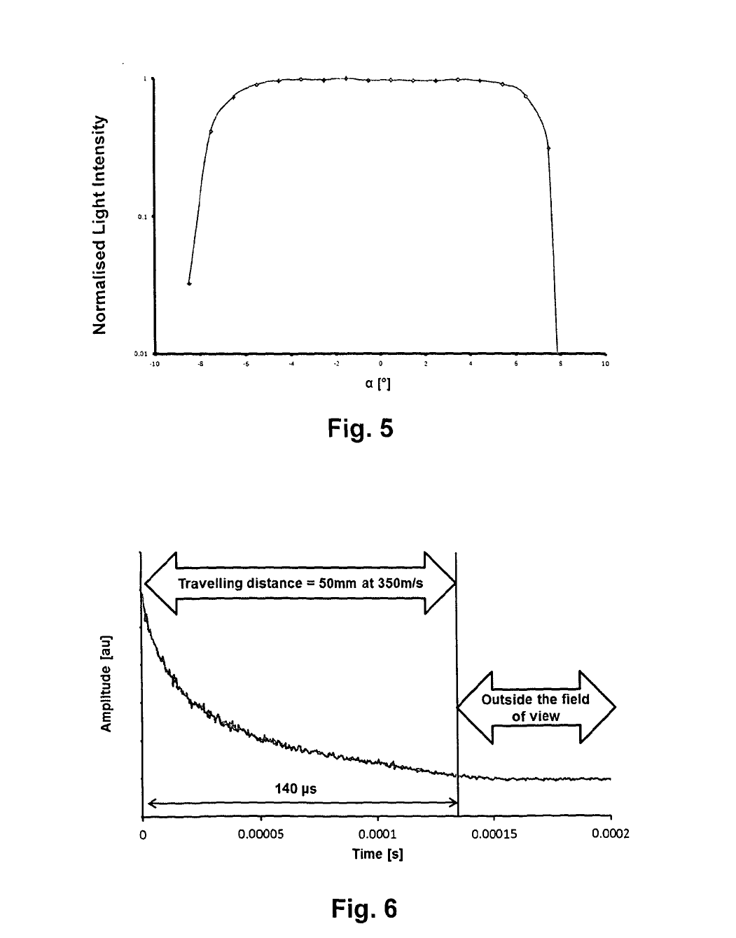

FIG. 5 illustrates the measured light intensity as a function of the angle of incidence (α) to the optical axis of the probe of the probe assembly of the detection system of FIG. 1 in Example #2;

FIG. 6 illustrates the intensity decay of a laser-illuminated spot on a rotating YAG:Eu-coated turbine blade of a gas turbine as measured across the field of view of the probe of the probe assembly of the detection system of FIG. 1 in Example #3;

FIG. 7 illustrates a first modified optical probe assembly for the detection system of FIG. 1;

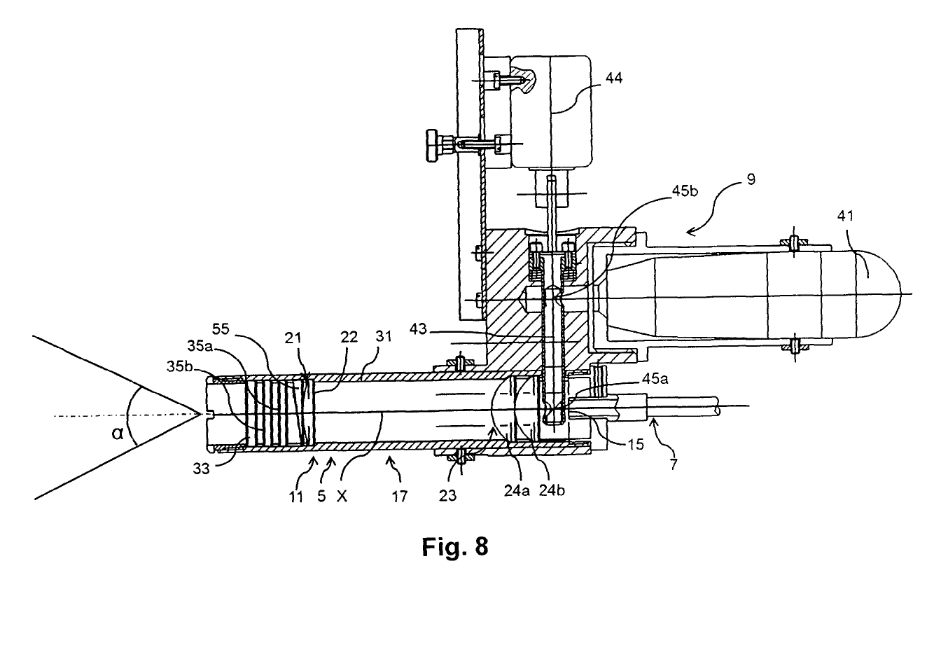

FIG. 8 illustrates a second modified optical probe assembly for the detection system of FIG. 1;

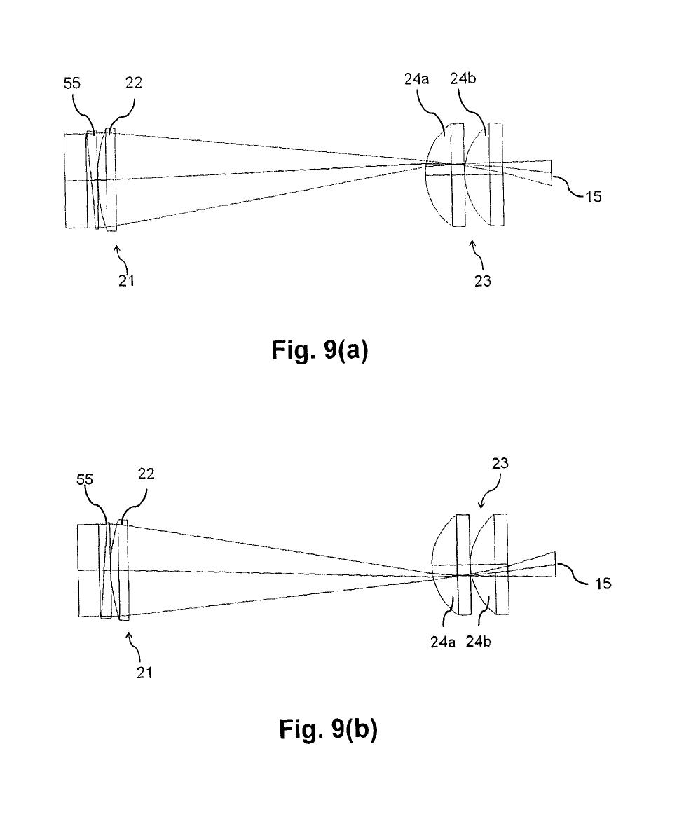

FIGS. 9(a) and (b) illustrate ray diagrams for the optical probe assembly of FIG. 8, which illustrate the focussing and relaying of light energy with the wedge prism oriented in two positions 180 degrees apart, thick edge up in FIG. 9(a) and thick edge down in FIG. 9(b);

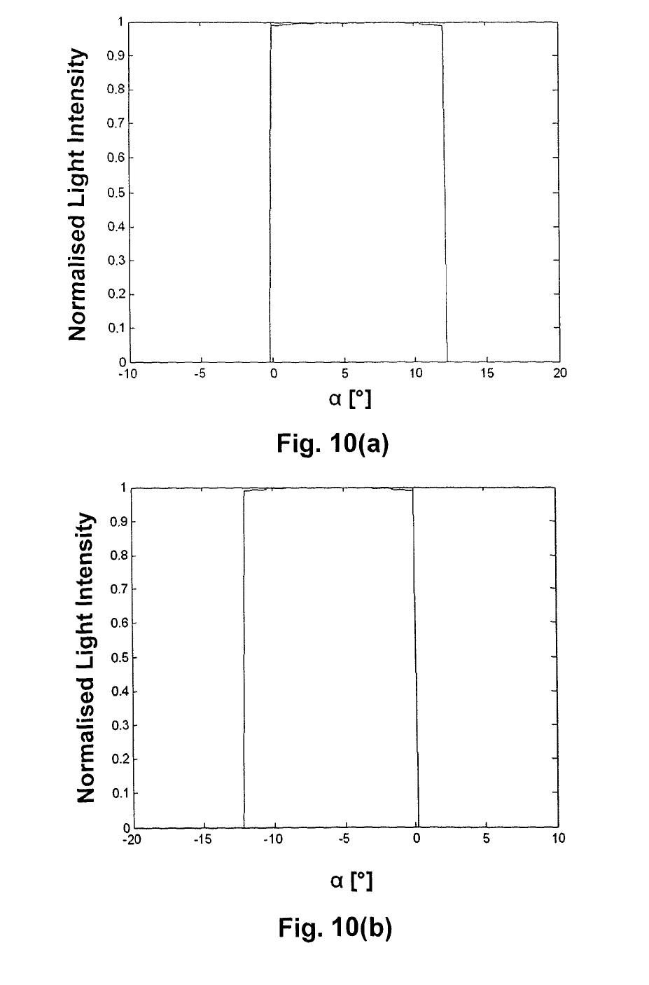

FIGS. 10(a) and (b) illustrate the theoretical light intensity as a function of the angle of incidence (α) to the optical axis of the probe for the optical arrangements of FIGS. 9(a) and (b);

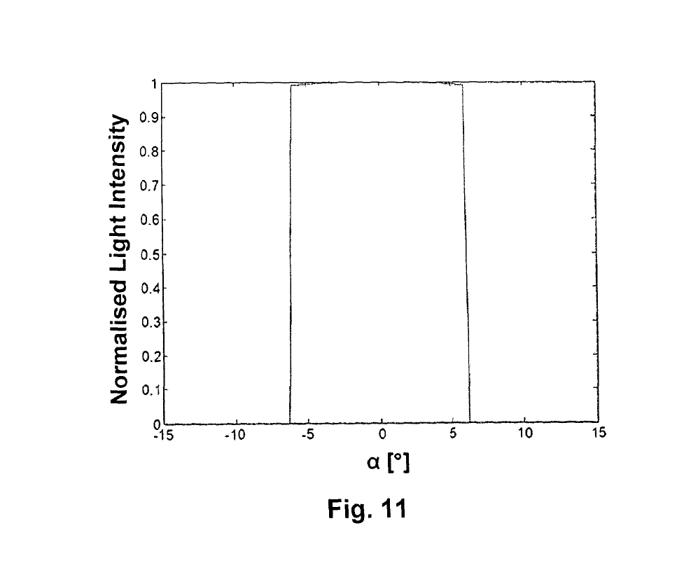

FIG. 11 illustrates a theoretical light intensity profile for the optical system of FIG. 9 where comprising no wedge prism;

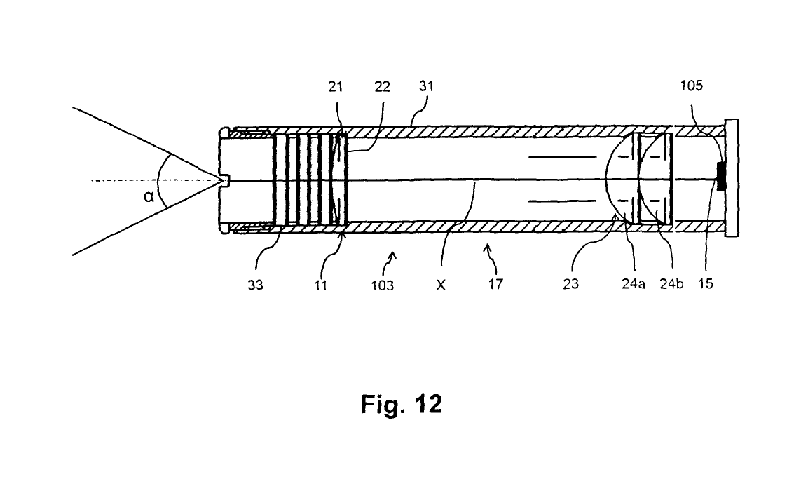

FIG. 12 illustrates a photovoltaic module in accordance with a preferred embodiment of the present invention;

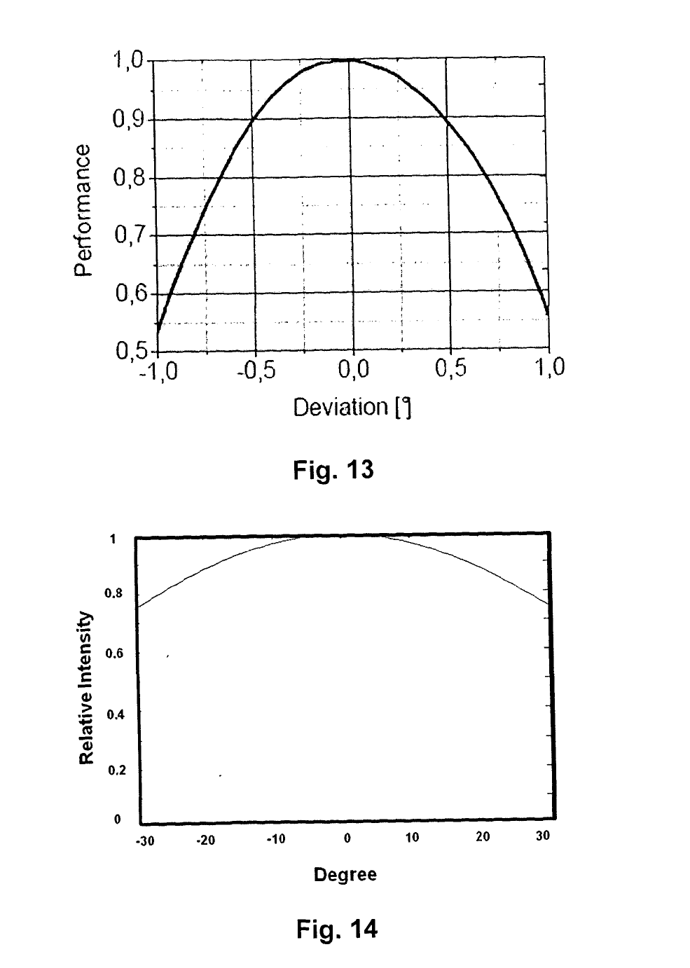

FIG. 13 illustrates the relative intensity as a function of the angle of incidence for the optical apparatus of the photovoltaic module of FIG. 12;

FIG. 14 illustrates the efficiency of a conventional concentrated photovoltaic (CPV) element as a function of the deviation from a zero angle of incidence; and

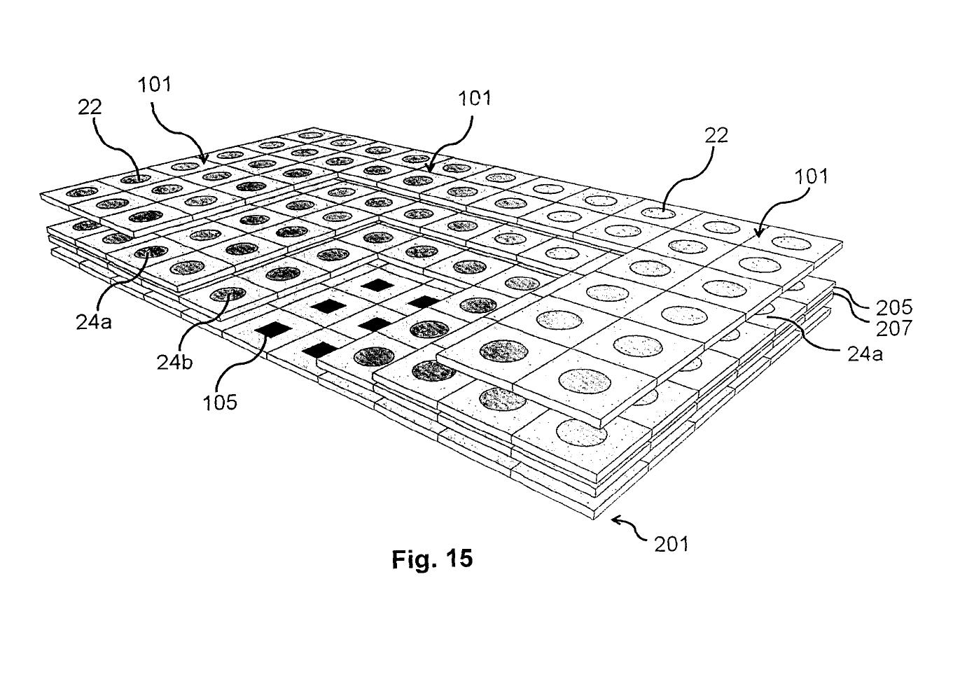

FIG. 15 illustrates a photovoltaic array in accordance with a preferred embodiment of the present invention.

FIG. 1 illustrates a detection system in accordance with a preferred embodiment of the present invention.

The detection system comprises a light source 1 for irradiating a spot on a moving object O, an optical probe assembly 3 for collecting light energy from the irradiated spot on the object O when within a field of view of the probe assembly 3, and a photodetector 4, in this embodiment a photomultiplier tube (PMT), for measuring the intensity of the light energy collected by the probe assembly 3.

The light source 1 is configured to provide a collimated light beam, here a UV beam, for a short, predetermined period to irradiate a spot on the object O at an upstream end of the field of view of the probe assembly 3, and, during movement of the object O across the field of view of the probe assembly 3, the light energy from the luminescence generated by the irradiated spot on the object O is collected by the probe assembly 3 and detected by the photodetector 4, such as to measure the lifetime decay of the luminescence, from which a characteristic of the object O can be determined.

As illustrated in FIGS. 2(a) and (b), the probe assembly 3 comprises an optical probe 5 for transferring light energy from the object O, a light collector 7 for collecting light energy transferred by the probe 5, and a camera unit 9 for enabling visual inspection of the object O along the optical axis X of the probe 5.

The probe 5 comprises an optical system 11 for transferring light energy from the object O along a ray path which has an aperture 15 of substantially common size and location independent of the location of the object O within the field of view of the optical system 11, and a housing 17 for housing the optical system 11.

With this configuration, a two-dimensional energy distribution is achieved across the common aperture 15 which is independent of the location of the object O within the field of view of the optical system 11. In this embodiment the optical system 11 does not have a unique focal point which remains the same regardless of the location of the object O, either in terms of angle or distance. This is achieved by collecting a large bundle of light from different angles across the field of view of the optical system 11 and transferring this bundle of light uniformly onto a relatively-small aperture 15.

This energy distribution is particularly advantageous, in that the effect of imperfections at the aperture 15, such as by way of dust or damage, is limited. This contrasts with an imaging system in which one location on the image plane corresponds to a respective angle in the field of view, meaning that, if a point on the image plane is obstructed, no light can be collected from the corresponding angle in the field of view. This limited effect of obstructions or damage at the aperture 15 provides a robust, flat hat energy transfer function.

A further advantage of this configuration is that light energy can be collected simultaneously from a plurality of objects O located at different distances from the common aperture 15, with modification. In preferred embodiments light energy can be collected from objects O located at distances of from about 1 cm to about 2.5 cm, preferably from about 1 cm to about 10 cm, preferably from about 1 cm to about 60 cm, preferably from about 1 cm to about 2 m, preferably from about 1 cm to about 20 m, and more preferably from about 1 cm to infinity, without any modification.

In this embodiment the optical system 11 has a field of view of about 12° over which substantially 100% of the light energy passes through the common aperture 15. With this relatively wide field of view, in which there is no functional deviation in the measured light intensity, the probe 5 allows for the measurement of light intensity without any de-convolution of the detected signal.

In one embodiment the ratio of the diameter of the collected light bundles and the common, exit aperture 15 is controllable, and preferably greater than 1, 2, 3, 4, 5, 10, 50, 100, 250 or 500; this ratio being referred to as the concentration factor.

The optical system 11 comprises a first optical element 21, in this embodiment comprising a single lens 22, for focussing incident radiation from the object O to a focal point, and a second optical element 23, in this embodiment comprising a plurality of, here first and second lenses 24a, 24b, for relaying the image of the first optical element 21 to the common aperture 15 independent of the location of the light source when within the field of view of the optical system 11. FIG. 3 illustrates ray diagrams, which illustrate the focussing and relaying of light energy from the object O to the common aperture 15 independent of the location of the object O when within the field of view of the optical system 11.

In this embodiment the lens 22 of the first optical element 21 has a first, front surface of radius 36.68 mm, a second, rear surface of radius infinity and a centre thickness of 3.9 mm.

In this embodiment the first lens 24a of the second optical element 23 has a first, front surface of radius 14.446 mm, a second, rear surface of radius infinity and a centre thickness of 8.7 mm, and the first surface of the first lens 24a of the second optical element 23 is spaced 70 mm from the second surface of the lens 22 of the first optical element 21.

In this embodiment the second lens 24b of the second optical element 23 has a first, front surface of radius 14.446 mm, a second, rear surface of radius infinity and a centre thickness of 8.7 mm, and the first surface of the second lens 24b of the second optical element 23 is spaced 0.1 mm from the second surface of the first lens 24a of the second optical element 23.

In this embodiment the lenses 22, 24a, 24b are formed of fused silica.

In this embodiment the lenses 22, 24a, 24b are formed as conventional lenses, but could be formed as Fresnel lenses.

In this embodiment the common aperture 15 comprises a circular aperture, but could comprise any other shape, for example, square or polygonal.

In this embodiment the common aperture 15 is located 11 mm from the second surface of the second lens 24b of the second optical element 23.

In this embodiment the common aperture 15 is at other than a focal or image plane, here at an aperture plane. This configuration is particularly advantageous, in providing for a substantially uniform or flat hat energy distribution over the common aperture 15 and avoiding hot spots, which is particularly suited to detection systems. In preferred embodiments the uniformity is an intensity variance of less than about 15%, preferably less than about 10%, and more preferably less than about 5%. This contrasts with an imaging system which focuses the light source energy at respective, different locations on the image plane in order to recreate the image.

In this embodiment the rays are diverging at the common aperture 15. In preferred embodiments the light rays entering the aperture 15 have an angle about 10 degrees.

In this embodiment the use of a plurality of lenses 24a, 24b for the second optical element 23 produces a short effective focal length, thereby reducing the diameter of the common aperture 15.

In an alternative embodiment the second optical element 23 could comprise a single lens.

In this embodiment the collector 7 comprises a bundle of optical fibres, which is coupled to the detector 4.

In this embodiment the housing 17 comprises a housing body 31, here cylindrical in shape, in which the first and second optical elements 21, 23 and the collector 7 are aligned on a common optical axis X, and a window 33 is located at a front end of the housing body 31.

In this embodiment the optical system 11 further comprises at least one, here a plurality of filters 35a, 35b for suppressing the transfer of unwanted light, such as UV or strong infra-red black body radiation, to the detector 4.

In this embodiment the filters 35a, 35b are located forwardly of the first optical element 21. In other embodiments one or more of the filters 35a, 35b could be located elsewhere in the optical path, such as between the first and second optical elements 21, 23.

In this embodiment the window 33 has a thickness of 3 mm, and is formed of sapphire.

The camera unit 9 comprises a camera 41 for imaging the object O, an optical coupler 43 which movable between a first, inoperative position, as illustrated in FIG. 2(a), and an operative position, as illustrated in FIG. 2(b), in which the coupler 43 optically couples the camera 41 to the probe 5 to capture an image along the optical axis X of the probe 5, and an actuator 44 for moving the coupler 43 between the operative and inoperative positions.

In this embodiment the coupler 43 comprises first and second prisms 45a, b which are arranged such that the camera 41 is optically coupled to the optical axis X of the probe 5 when in the operative position, and the coupler 43 is withdrawn from the optical path of the probe 5 in the inoperative position.

In this embodiment the actuator 44 comprises a solenoid which is actuatable to move the coupler 43 between the operative and inoperative positions.

The present invention will now be described with reference to the following non-limiting Example.

### EXAMPLE #1

Using an LED as a light source, located at a distance of 36 cm ahead of the probe 5, a two-dimensional map of the light intensity detected by the probe 5 was measured.

FIGS. 4(a) and (b) illustrate the measured light intensity as a function of the angle of incidence (α) to the optical axis X of the probe 5 along two orthogonal (X, Y) axes, respectively, as compared to the theoretical intensity functions predicted using ZEMAX software (ZEMAX Development Corporation, USA).

As will be observed, the measured field of view in the X axis is 11±2°, which compares to a predicted field of view of 12°, and the measured field of view in the Y axis is 12±2°, which compares to a predicted field of view of 12°.

As will also be observed, the measured shift of the field of view in the X axis is 0.5±1°, which compares to a predicted shift of the field of view of 0°, and the measured shift of the field of view in the Y axis is 7±1°, which compares to a predicted shift of the field of view of 7°.

### EXAMPLE #2

Using an LED as a light source, located at a distance of 200 cm ahead of the probe 5, where modified to be symmetrical about the optical axis X by having no prism or fiber through the lenses, a two-dimensional map of the light intensity detected by the probe 5 was measured.

FIG. 5 illustrates the measured light intensity as a function of the angle of incidence (α) to the optical axis X of the probe 5. As will be observed, the measured field of view is 12±2°.

### EXAMPLE #3

The phosphorescence of a YAG:Eu-coated turbine blade of a gas turbine, here operated at a speed of 13000 rpm, was measured using the probe 5.

The probe 5 was located at a distance of 400 mm from the turbine blades of the gas turbine, and the illumination was provided by a laser having a wavelength of 532 nm and a spot diameter of 10 mm.

The phosphorescence was measured at a wavelength of 620 nm, and the intensity decay is illustrated in FIG. 6 across the field of view, which corresponds to a distance of 50 mm and a duration of 140 μs at a speed of 350 m/s. In this Example, the lifetime decay corresponded to a temperature of 733K.

FIG. 7 illustrates a first modified optical probe assembly 3 for the detection system of FIG. 1.

The probe assembly 3 of this embodiment is quite similar to the probe assembly 3 of the above-described embodiment, and thus, in order to avoid unnecessary duplication of description, only the differences will be described in detail, with like parts being designated by like reference signs.

In this embodiment the camera unit 9 is modified to omit the actuator 44 and include a stationary dichroic element 51, here a dichroic mirror, in place of the prisms 45a, b, which diverts light from the visible spectrum to the camera unit 9, and still allows the optical system 11 to transfer light energy from the object O to the common aperture 15. This arrangement advantageously provides for visual inspection of the object O without requiring dynamic intrusion into the optical path.

In this embodiment the dichroic element 51 is located between the second optical element 23 and the common aperture 15.

FIG. 8 illustrates a second modified optical probe assembly 3 for the detection system of FIG. 1.

The probe assembly 3 of this embodiment is very similar to the probe assembly 3 of the first-described embodiment, and thus, in order to avoid unnecessary duplication of description, only the differences will be described in detail, with like parts being designated by like reference signs.

In this embodiment the optical system 11 of the probe 5 further comprises a wedge prism 55 located forward of the lens 22 of the first optical element 21.

In this embodiment the wedge prism 55 has a wedge angle of 7 degrees and is formed of fused silica.

The wedge prism 55 acts to tilt the acceptance angle of the probe 5 relative to the optical axis X of the probe 5, and thereby allows for adjustment of the acceptance angle of the probe 5 without requiring physical movement of the probe 5. The ability to adjust the acceptance angle is advantageous, particularly with slower-moving light sources, in allowing the light source to be maintained within the field of view when otherwise the light source would fall outside the normal field of view.

FIGS. 9(a) and (b) illustrate ray diagrams, which illustrate the focussing and relaying of light energy from the object O to the common aperture 15 with the wedge prism 55 oriented in two positions 180 degrees apart, thick edge up in FIG. 9(a) and thick edge down in FIG. 9(b).

FIGS. 10(a) and (b) illustrate the theoretical light intensity as a function of the angle of incidence (α) to the optical axis X of the probe 5 for the optical arrangements of FIGS. 9(a) and (b), predicted using ZEMAX software. As will be observed, the field of view shifts oppositely into the positive and negative fields of view with the wedge prism 55 oriented in the two opposite positions. These light intensity profiles can be compared to the counterpart theoretical light intensity profile for the optical system 11 where comprising no wedge prism 55, as illustrated in FIG. 11, again predicted using ZEMAX software.

In one embodiment the wedge prism 55 can be coupled to a drive mechanism, such as a mechanical or electro-mechanical system, which rotates the wedge prism 55 to follow the light source.

In another embodiment, such as where the probe 5 can only be mounted with a particular orientation, the wedge prism 55 can have a fixed position which provides for the acceptance angle to have a predetermined inclination, for example, in relation to the path of the sun, where the sun is a light source.

FIG. 12 illustrates a photovoltaic module 101 in accordance with a preferred embodiment of the present invention.

The photovoltaic module 101 comprises an optical apparatus 103, which incorporates an optical system 11 of the same kind as the above-described embodiment, and a photovoltaic cell 105 located at the common aperture 15 of the optical system 11. In order to avoid unnecessary duplication of description only the differences will be described in detail, with like parts being designated by like reference signs.

In this embodiment the optical system 11 has a field of view of about 12° over which substantially 100% of the light energy passes through the common aperture 15.

FIG. 14 illustrates the relative intensity as a function of the angle of incidence for the optical apparatus 103 of FIG. 12. As will be observed, the optical apparatus 103 provides for a relative intensity of about 75% at an angle of incidence of about 30°. This compares remarkably with existing concentrated photovoltaic (CPV) systems, which exhibit a relative intensity of only about 50% at an angle of incidence of 1°, as illustrated in FIG. 13.

By having a relatively wide field of view, the photovoltaic module 101 of the present invention allows for use with a simple tracking mechanism, for example, which could be moved between a number of fixed positions, typically 10 positions, during the day, and still would collect substantially 100% of the available solar energy.

FIG. 15 illustrates a photovoltaic array 201 in accordance with a preferred embodiment of the present invention.

The photovoltaic array 201 comprises a plurality of the photovoltaic modules 101 of the kind of the above-described embodiment. In this embodiment the lenses 22, 24a, 24b of the optical elements 21, 23 are fabricated as Fresnel lenses in separate sheets 203, 205, 207 located above the photovoltaic cells 105.

Finally, it will be understood that the present invention has been described in its preferred embodiments and can be modified in many different ways without departing from the scope of the invention as defined by the appended claims.

For example, in the first-described embodiment, the optical elements 21, 23 are implemented using refractive optics, but these optical elements 21, 23 could instead be implemented in reflective or diffractive optics.

1. An optical system for transferring light energy from a light source, in particular a moving light source, to a common aperture independent of the location of the light source within a field of view, wherein the light energy distribution is preferably substantially uniform over the area of the common aperture.

2. The optical system of claim 1, having a field of view of at least about 5°, 8°, 10° or 12° over which substantially 100% of the light energy passes through the common aperture.

3. (canceled)

4. (canceled)

5. (canceled)

6. The optical system of claim 1, wherein the optical system allows for detection of light intensity at the common aperture without any de-convolution of the detected light.

7. The optical system of claim 1, comprising a first optical element for focussing incident radiation from the object to a focal point, and a second optical element for relaying the image of the first optical element to the common aperture independent of the location of the light source when within the field of view, optionally the first optical element comprises a single lens, optionally the second optical element comprises a single lens or a plurality of lenses, optionally the lenses are formed as Fresnel lenses.

8. (canceled)

9. (canceled)

10. (canceled)

11. (canceled)

12. The optical system of claim 7, further comprising a wedge prism located forward of the first optical element, optionally further comprising a drive mechanism which rotates the wedge prism to follow the light source or the wedge prism has a fixed position which provides for the field of view to have a predetermined inclination relative to an optical axis of the optical system.

13. (canceled)

14. (canceled)

15. The optical system of claim 1, wherein the common aperture comprises a circular, square or polygonal aperture and/or further comprising one or more filters for suppressing the transfer of unwanted light.

16. The optical system of claim 1, wherein the common aperture is at other than a focal or image plane.

17. The optical system of claim 1, wherein the rays are diverging at the common aperture.

18. (canceled)

19. (canceled)

20. (canceled)

21. A probe assembly, comprising:
a probe comprising the optical system of claim 1; and
a light collector for collecting light energy transferred by the probe, optionally the collector comprises a bundle of optical fibres.

22. (canceled)

23. The probe assembly of claim 21, further comprising:
a camera unit for enabling visual inspection of the object along an optical axis of the probe, optionally the camera unit comprises a camera for imaging the object, and an optical coupler which is operable optically to couple the camera to the probe to capture an image along the optical axis of the probe.

24. The probe assembly of claim 23, wherein the camera unit comprises a camera for imaging the object, and an optical coupler which is operable optically to couple the camera to the probe to capture an image along the optical axis of the probe, optionally (i) the coupler is moveable between an operative position in which the coupler optically couples the camera to the probe to capture an image along the optical axis of the probe and an inoperative position, and the camera unit further comprises an actuator which is actuatable to move the optical coupler between the operative and inoperative positions, optionally the coupler comprises first and second prisms which are arranged such that the camera is optically coupled to the optical axis of the probe when in the operative position, and the coupler is withdrawn from the optical path of the probe in the inoperative position, or (ii) the coupler comprises a dichroic element which is located on the optical axis of the probe and diverts light from the visible spectrum to the camera.

25. (canceled)

26. (canceled)

27. (canceled)

28. A detection system, comprising:
a light source for irradiating a spot on a moving object;
the probe assembly of claim 21 for collecting light energy from the irradiated spot on the object when within a field of view of the probe; and
a photodetector for measuring the intensity of the light energy collected by the probe;
optionally the light source is configured to provide a collimated light beam for a predetermined period to irradiate a spot on the object at an upstream end of the field of view of the probe, and, during movement of the object across the field of view of the probe, the light energy from luminescence generated by the irradiated spot on the object is collected by the probe and detected by the photodetector.

29. (canceled)

30. A photovoltaic module comprising the optical system of claim 1, and a photovoltaic cell located at the common aperture of the optical system, optionally the optical system provides for a relative intensity of at least about 50%, at least about 60%, at least about 70% or at least about 75% at an angle of incidence of about 30°.

31. (canceled)

32. (canceled)

33. (canceled)

34. (canceled)

35. A photovoltaic array comprising a plurality of the photovoltaic modules of claim 30.

36. A photovoltaic array, comprising:
a plurality of optical systems for transferring light energy from a light source, in particular a moving light source, to common apertures independent of the location of the light source within a field of view, wherein each optical system comprises a first optical element for focussing incident radiation from the light source to a focal point, and a second optical element for relaying the image of the first optical element to the common aperture independent of the location of the light source when within the field of view; and
a plurality of photovoltaic cells located respectively at the common apertures of the optical systems.

37. The photovoltaic array of claim 36, wherein the optical elements are fabricated as Fresnel lenses in separate sheets located above the photovoltaic cells.

38. The photovoltaic array of claim 36, wherein the first optical element comprises a single lens and/or the second optical element comprises a single lens or a plurality of lenses.

39. (canceled)

40. (canceled)

41. The photovoltaic array of claim 36, wherein each optical system further comprises a wedge prism located forward of the first optical element, optionally the wedge prism has a fixed position which provides for the field of view to have a predetermined inclination relative to an optical axis of the optical system.

42. (canceled)

43. A photovoltaic system, comprising:
the photovoltaic module or array of claim 30; and
a tracking mechanism for moving the photovoltaic module or array to follow the path of the sun.

44. The photovoltaic system of claim 43, wherein the tracking mechanism is operative to move the photovoltaic module or array between a plurality of fixed positions over a period of one day, optionally the tracking mechanism is operative to move the photovoltaic module or array between not more than 10 positions, not more than 8 positions or not more than 5 positions over a period of one day.

45. (canceled)

46. (canceled)

47. (canceled)
